(19) United States
(12) Patent Application Publication
(10) Pub. No.: US 2026/0124943 A1
(43) Pub. Date: May 7, 2026

(54) COOLING APPARATUS FOR COOLING CHARGING CONTACTS AND/OR CHARGING LINES, METHOD FOR OPERATION THEREOF, AND VEHICLE HAVING SAID COOLING APPARATUS

(71) Applicant: Dr. Ing. h.c. F. Porsche Aktiengesellschaft, Stuttgart (DE)

(72) Inventors: Jörg Baumgartner, Pfinztal (DE); Philipp Krause, Aichtal (DE); Dominik Beierl, Korntal-Münchingen (DE)

(73) Assignee: Dr. Ing. h.c. F. Porsche Aktiengesellschaft, Stuttgart (DE)

(21) Appl. No.: 19/338,130

(22) Filed: Sep. 24, 2025

(30) Foreign Application Priority Data
Nov. 5, 2024 (DE) 102024132076.1

(51) Int. Cl. B60L 53/302; B60L 53/16; H05K 7/20

(52) U.S. Cl. CPC B60L 53/302; B60L 53/16; H05K 7/20154; H05K 7/20209; B60L 2240/36

(57) ABSTRACT

A cooling apparatus for cooling charging contact data and/or charging lines. The cooling apparatus includes a forced vent configured so as to convey air from an interior of the vehicle to the outside. The cooling apparatus further includes an air duct having an air duct outlet configured so as to provide a flow of air from the forced vent to the charging contacts and/or charging lines. A fan is configured so as to cause or form the air flow in the air duct.

### CROSS-REFERENCE TO RELATED APPLICATION

This application claims priority to German Patent Application No. 10 2024 132 076.1, filed Nov. 5, 2024, the content of such application being incorporated by reference herein in its entirety.

### FIELD OF THE INVENTION

The present application relates to a cooling apparatus for cooling charging contacts or charging boxes and/or charging lines as well as a method for operating the cooling apparatus according to aspects of the invention. The application further relates to a vehicle comprising the cooling apparatus according to aspects of the invention.

### BACKGROUND OF THE INVENTION

When charging traction batteries of hybrid vehicles or battery-electric vehicles at a charging point, due to the high current flow, high temperatures arise on the charging contacts of the charging connection as well as on the power lines (charging lines) leading to the high-voltage system, in particular the traction battery. A high-voltage (HV) system within the meaning of the application refers to the part of the electrical system of the vehicle that is exposed to a high-volt power. This includes, in particular, the traction battery and its charging management system, as well as an electric traction machine and its pulse inverter. Accordingly, an HV charging interface describes a charging interface for charging the traction battery. In order to enable short charging times, as much electrical energy as possible is supplied into the traction battery in as short a time as possible, thereby increasing the temperature load on the charging contacts and the charging lines. Very high temperatures are reached, especially when charging with direct current (DC charging).

If the temperature exceeds a maximum permissible temperature, the charging operation must be throttled or even discontinued for safety reasons. This leads to longer wait times when charging the battery, and thus possibly to customer displeasure.

Thus, there is a need to cool the charging contacts and/or the charging lines. There are different approaches for this. While active cooling systems with cooling plates and fluid circuits are effective, they are also complex and costly to install and maintain. In order to achieve a better passive cooling, bus bars are used instead of circular cables, which can better remove the waste heat due to the altered geometry. In the context of the application, both round cables and bus bars are understood to mean charging lines. Generally, the cooling systems must be robust enough to function reliably even in the case of extreme outside temperatures. At the same time, they should be as compact and lightweight as possible so as not to add too much additional weight to the vehicle or take up too much space in the vehicle. The development of efficient and cost-efficient cooling concepts for charging ports therefore remains an important task for the automotive industry in order to further optimize the fast charging of electric vehicles.

Various systems for efficient and effective cooling are proposed in the prior art. Documents DE 10 2022 118 838 A1 and DE 10 2022 122 763 A1, respectively, which are incorporated by reference herein, describe a device for cooling a charging box and the charging contacts and charging lines of an automobile contained therein, which box comprises an air duct connected to an interior of the motor vehicle, wherein the air duct comprises a fan, and wherein the air duct is configured so as to supply the DC contacts of the charging box with power. However, such systems have the disadvantage that they represent an acoustic connection from outside the vehicle to the interior, and they must be acoustically isolated accordingly in order not to reduce the comfort for occupants.

Document DE 10 2021 112 623 A1, which is incorporated by reference herein, describes a device for cooling a charging box of a motor vehicle, which comprises an air duct connected to an outer surface of the motor vehicle, wherein the air duct comprises a fan, and wherein the air duct is configured so as to supply DC contacts of the charging box with power. However, the problem here arises, in particular in the case of high outside temperatures, that a cooling of the charging contacts can only be carried out in an inefficient manner.

### SUMMARY OF THE INVENTION

In light of the described background, the present invention provides an alternative and improved form of the cooling apparatus for cooling charging contacts and/or charging lines of an HV charging interface in a vehicle.

The cooling apparatus according to aspects of the invention comprises a forced vent configured so as to convey air from an interior of the vehicle to the outside. Forced ventilation in a vehicle is a system specifically designed to selectively remove exhaust air and moisture from the interior, without the user being able to manually regulate it. Thus, the system is designed so as to actively direct exhaust air out of the vehicle. It is used in particular in order to enable effective air conditioning in the vehicle and to establish a pressure balance between the interior of the vehicle and the vehicle surroundings. Often, ventilators or fans are used in order to induce an air flow outwardly from the vehicle interior. Modern vehicles, in particular having a climate control system, referred to in the application as air conditioning, typically have a forced vent. No second forced vent is required, but rather the forced vent already provided in the vehicle can be part of the cooling apparatus.

The cooling apparatus according to aspects of the invention further comprises an air duct having an air duct outlet configured so as to provide a flow of air from the forced vent to the charging contacts and/or charging lines, wherein a fan is further provided, being configured so as to cause or form the air flow in the air duct.

With the cooling apparatus according to aspects of the invention, the charging contacts and charging lines of the vehicle can be cooled by the interior air, in particular during a charging operation. The comparatively cool interior vehicle air is guided onto the charging contacts and/or charging lines to be cooled, whereby a so-called forced convection benefits the heat dissipation. This in particular provides the advantage that, in addition to the forced vent provided in the vehicle anyway, no further passage to the exterior area of the vehicle is produced from the interior. A forced vent is installed in the vehicle anyway due to the above-described problems, and is often in close proximity to the charging box and thus the charging contacts, as long as that the forced vent is provided in the rear region, so that the air duct between the forced vent and the charging box can be kept short. Further, forced vents are already isolated from the exterior area of the vehicle, so that no further sound insulation needs to be implemented here due to the cooling apparatus. Likewise, the air from the interior is used in order to cool the charging contacts and/or charging lines, so that even in the case of hot external conditions, air that is conditioned for the interior anyway can also be used for cooling, and thus the cooling can be carried out efficiently regardless of the external conditions.

In an advantageous embodiment of the invention, the forced vent comprises an acoustic hood configured so as to prevent sound transmission from outside of the interior into the interior of the vehicle. An acoustic hood of a forced vent in a vehicle is to be understood as a sound-absorbing cover through which air discharged from the interior is conducted. Its main purpose is to reduce the noise produced by the forced vent and thus lower the noise level in the vehicle interior. For this purpose, it comprises a corresponding acoustic insulation section through which air can flow outwardly from the vehicle interior, but any sound is retained, at least from the outside inwardly.

The fan of the cooling apparatus is preferably arranged in the acoustic hood, in particular in the direction of flow of the air through the acoustic hood, behind an acoustic insulation section. Thus, both the air duct of the cooling apparatus and the outlet of the forced vent, which typically also comprises a forced vent, can be acoustically isolated by an insulation section in the acoustic hood so as to vent the interior. In other words, the air that flows into the acoustic hood for forced venting is divided and flows out through the air duct for cooling the charging contacts and/or the charging lines on the one hand and directly through an outlet of the forced vent on the other hand. If the cooling apparatus is not activated, the air flows completely through the outlet of the forced vent.

In a further advantageous embodiment of the invention, the air duct outlet comprises air-conducting elements configured so as to selectively discharge air from the air duct. A better focus of the discharged air flow on the elements to be cooled can thus be ensured in order to achieve as high an efficiency as possible of the cooling apparatus.

In a further advantageous embodiment of the invention, the cooling apparatus comprises a heat sink having direct contact with the charging contacts and/or the charging lines, wherein the air duct outlet is at least partially aimed at the heat sink. Accordingly, at least a portion of the air flowing from the air duct outlet is directed towards the heat sink. Through the heat sink, the heat dissipation from the charging contacts or charging lines can be improved. A simple shape of a heat sink consists of a body having ribs arranged in parallel. Such heat sinks are known from a wide field of applications, for example CPU cooling.

Further advantageous is such an embodiment with a heat sink, in which the heat sink is fixed to a charging box carrying the charging contacts via a spacing apparatus and the heat sink carries the charging lines within itself. Thus, the heat of the charging lines is transferred to the heat sink and is carried away by the incoming air flow. An introduction of force into the plug contacts of the charging box can be prevented by the spacing apparatus. It thus absorbs forces that could arise, for example, due to deformation or movement of the charging lines as a result of a mechanical impact during charging, e.g., when inserting or detaching the charging plug, or due to thermal deformations and could directly impair a sensible attachment of the heat sink to the charging contacts. If a heat sink is mounted directly on the charging contacts, this could lead to stresses in the cooling plate and the connection to the charging contacts, which could cause damage in the event of the above-mentioned deformations or movements. The spacing apparatus allows the heat sink to be stable and to be arranged in a certain location, while the charging lines can still move flexibly, and thus deformations and movements can be compensated.

An embodiment of the invention in which the air duct outlet is arranged below the charging contacts and/or the charging lines is further advantageous. Accordingly, in embodiments with a heat sink, the air duct outlet is also preferably arranged below the heat sink. “Below” is understood to mean a positioning closer to the ground in the z-direction of the vehicle, i.e., in its vertical direction. The outflowing air must thus flow upwards against gravity, thereby slowing it down. However, due to the heating, the lighter air then rises further and can escape upwards without air flowing against it.

The method during a charging operation of a traction battery of a vehicle comprises a plurality of steps. First, a temperature of the charging contacts is detected. The temperature of the charging contacts is then compared to a permissible temperature of the charging contacts. If the temperature of the charging contacts is less than the permissible temperature of the charging contacts, a comparison of the temperature of the charging contacts to a switch-on temperature of the fan of the cooling apparatus takes place. If the temperature of the charging contacts is greater than the permissible temperature of the charging contacts, there is a threat of overheating of the charging interface, in particular of the charging contacts, and the charging operation is preferably discontinued. The switch-on temperature of the fan refers to the temperature of the air at the inlet of the fan and is to be understood as a temperature limit with respect to the charging contacts from which limit the fan is to be switched on.

If the temperature of the charging contacts is greater than the switch-on temperature of the fan, the fan is connected. Subsequently, the temperature of the charging contacts is compared to a switch-on temperature of the air conditioning. The switch-on temperature of the air conditioning refers to the temperature threshold of the air from which threshold the air conditioning is switched on. If the temperature of the charging contacts is greater than the switch-on temperature of the air conditioning or the calibrated temperature threshold for switching on the air conditioning system, the switching on of the air conditioning is carried out. As a result, the temperature in the interior of the vehicle can be kept or reduced below the temperature of the charging contacts. If the air conditioning would result in heating of the interior air, i.e., the input air on the fan, in particular above the temperature of the charging contacts, the activation of the air conditioning is omitted. With the method described, the cooling apparatus according to aspects of the invention can thus always be operated in order to bring about a cooling of the charging contacts. An air conditioning system of the vehicle is understood to mean a climate control system, which is configured so as to regulate the air temperature of the interior of the vehicle. In addition to an air conditioning system for cooling the air, it comprises a fan and a heater for heating the air.

In an advantageous embodiment of the method according to aspects of the invention, the switch-on temperature of the air conditioning is adjusted as a function of the temperature of the charging contacts, in particular by way of a charging management system. If the charging management system detects that the charging contacts or charging lines would have to be cooled with a cooler air, it activates the air conditioning of the climate system and initiates measures to cool the interior air.

The vehicle according to aspects of the invention comprises a cooling apparatus according to aspects of the invention.

### BRIEF DESCRIPTION OF THE DRAWINGS

The invention as well as advantageous aspects and embodiments thereof are explained in further detail below with reference to the accompanying figures. The figures show:

FIG. 1 shows a schematic illustration of an embodiment of the cooling apparatus according to aspects of the invention.

FIG. 2 shows a flow chart of an embodiment of the method according to aspects of the invention for operating the cooling apparatus.

FIG. 3 shows a perspective illustration of a second embodiment of the cooling apparatus according to aspects of the invention.

### DETAILED DESCRIPTION OF THE INVENTION

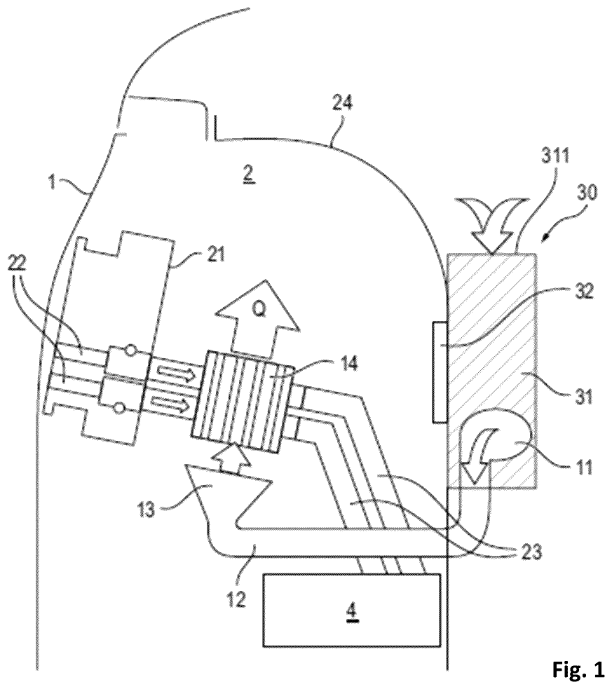

FIG. 1 shows a schematic illustration of an embodiment of the cooling apparatus according to aspects of the invention in a vehicle longitudinal cross-section. A charging box 21 having charging contacts 22, in particular DC contacts, is provided, wherein charging lines 23 lead from the charging contacts 22 to an HV system 4, consisting in particular of a traction battery. By means of a charging plug (not shown) of a charging point connected to the charging box 21 and the charging contacts 22, the traction battery can be charged via a current flow from the charging plug via the charging contacts 22 and the charging lines 23, thereby heating up charging contacts 22 and charging lines 23. The charging box 21 is arranged in an intermediate space 2 of the rear fender, between an outer skin 1 or panel and a vehicle interior. The intermediate space 2 is separated from the vehicle interior by an intermediate skin 24. The HV system 4 is not arranged in the intermediate space 2 as shown in the schematic illustration, but rather extends in particular in the vehicle floor.

The cooling apparatus comprises a forced vent 30, which is configured so as to convey air out of the interior. To this end, an acoustic hood 31 is arranged in the interior on the intermediate skin 24, which covers a forced vent 32 in the form of a fan. The forced vent 32 is provided so as to draw air out of the vehicle interior. The acoustic hood 31 comprises an opening 311, which is arranged on the upper side of the acoustic hood 31. Air is drawn by the forced vent 32 from the interior into the acoustic hood 31 through the opening 311 as indicated by arrows and blown into the intermediate space 2 from which it is discharged into the vehicle surroundings. The acoustic hood 31 comprises an acoustic insulation inside, which does not allow the acoustic emissions emitted by the vehicle exterior to be introduced into the vehicle interior, or only with reduced intensity.

Furthermore, a fan 11 of the cooling apparatus is provided in the acoustic hood 31. The fan 11 communicates with a cooling duct 12, which comprises a cooling duct outlet 13. The cooling duct outlet 13 terminates below a heat sink 14 and is aimed in the direction thereof. The acoustic insulation of the acoustic hood 31 is arranged between the fan 11 and the opening 311, so that the breakthrough shown through the cooling duct 12 is also acoustically isolated from the interior of the vehicle into the intermediate space 2 and thus the exterior of the vehicle by way of the acoustic insulation. The fan 11 conducts air from the acoustic hood 31 through the cooling duct 13 to the cooling duct outlet 13 and thereby generates an air flow. The latter is aimed towards the heat sink 14 through the cooling duct outlet 13. The heat sink 14 is directly in communication with the charging contacts 22 or charging lines 23 and comprises, for example, cooling fins for heat dissipation. The waste heat of the charging contacts 22 and the charging lines 23 is thereby received by the heat sink 14. The large surface area of the heat sink 14 improves the deheating of the charging contacts 22 and the charging lines 23.

The air flow directed towards the heat sink 14 from the vehicle interior thereby generates a forced convection and thus contributes positively to the deheating of the heat sink 14 and thus of the charging contacts 22 and the charging lines 23. These are cooled accordingly.

In order to maximize the effect of the air flow, air-conducting elements are provided at the air duct outlet 13, which allow for a targeted air flow, and thus a maximum proportion of the air flow for the cooling is used. By positioning the air duct outlet 13 below the heat sink 14 or the region to be cooled, it is achieved that, upon heating the heat-absorbing air, the air flow proceeds only in one direction, namely from the bottom to the top. Embodiments without heat sinks 14 are also contemplated, in which the air flow is aimed directly at charging contacts 22 and charging lines 23.

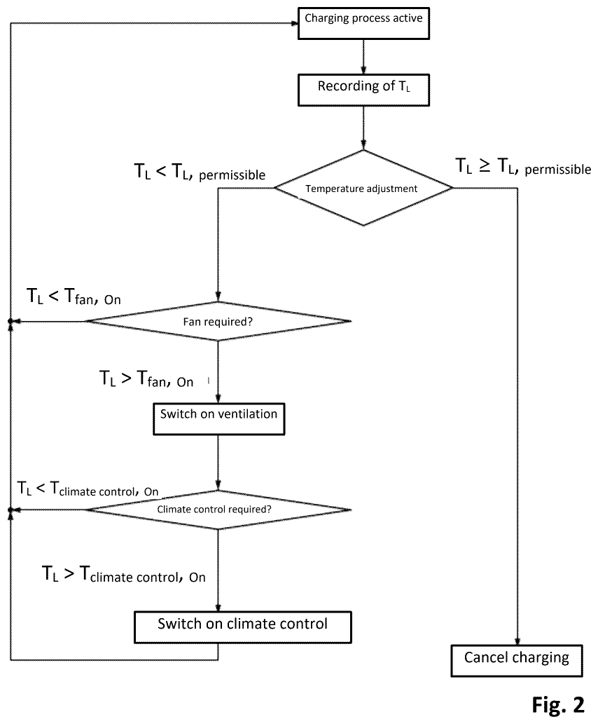

Typically, the charging box 12 and the forced vent 30 are not arranged in the transverse direction of the vehicle adjacent to one another, as shown in the schematic of FIG. 1, but rather in the longitudinal direction of the vehicle. Thus, the forced ventilation does not usually occur in the intermediate space 2 shown in FIG. 2, in which the charging box 12 is also arranged.

FIG. 2 shows a flow chart of an embodiment of the method according to aspects of the invention. Such diagrams are also referred to as logic diagrams. The method described herein may be performed, at least in part, by a computer having a processor, controller and memory containing software instructions.

According to the method according to aspects of the invention for operating the cooling apparatus according to aspects of the invention during a charging operation, a temperature of the charging contacts T_{L} is first measured. This is compared to a maximum permissible temperature of the charging contacts T_{L, permissible}. If the temperature of the charging contacts T_{L} exceeds the maximum permissible temperature of the charging contacts T_{L, permissible}, then the charging operation is throttled or even discontinued in order to avoid damage to the charging contacts and the charging line, or to rule out safety-critical conditions of the HV system or the charging system.

If the temperature of the charging contacts T_{L} is less than the maximum permissible temperature of the charging contacts T_{L, permissible}, then a further step is carried out in order to check whether the charging contacts 22 and/or the charging lines 23 can be cooled by the interior air. This is done by comparing the temperature of the charging contacts T_{L} to a switch-on temperature T_{fan, on} of the fan 11 of the cooling apparatus. If the temperature of the charging contacts T_{L} is greater than the switch-on temperature T_{fan, on} of the fan 11, then the fan 11 is switched on and thus the cooling apparatus is activated.

In a further method step, the temperature of the charging contacts T_{L} is compared to a switch-on temperature T_{climatecontrol, on} of the air conditioning. The air conditioning is to be understood as a climate control system of the vehicle, which lowers the interior temperature via an air conditioning system, heats the interior via a heater and, via a fan, transfers air from the exterior of the vehicle into the vehicle interior, or at least circulates the air inside the vehicle interior. If the temperature of the charging contacts T_{L} is greater than the switch-on temperature T_{climatecontrol, on} of the air conditioning, the air conditioning is connected.

Preferably, the temperature of the interior air, and thus the switch-on temperature T_{fan, on} of the fan 11, can be influenced via the control of the air conditioning. If the charging management system, which is responsible for controlling and monitoring the charging operation, detects that the internal temperature must be lowered for effective cooling, it can preferably access the air conditioning and lower the switch-on temperature, i.e., the target temperature of the air conditioning.

The cooling apparatus according to aspects of the invention and the method according to aspects of the invention thus ensure that even in the case of hot outside temperatures, the charging contacts and the charging lines, in which the interior air is used for cooling, are effectively cooled. These can be lowered as needed by the air conditioning of the vehicle in order to achieve more effective cooling. In addition, by removing the internal air from the forced vent 30, it can be ensured that the acoustic insulation of the forced vent 30 also sound-isolates the second breakthrough from the interior for the cooling apparatus in addition to the breakthrough of the forced vent, and thus a second sound insulation can be omitted.

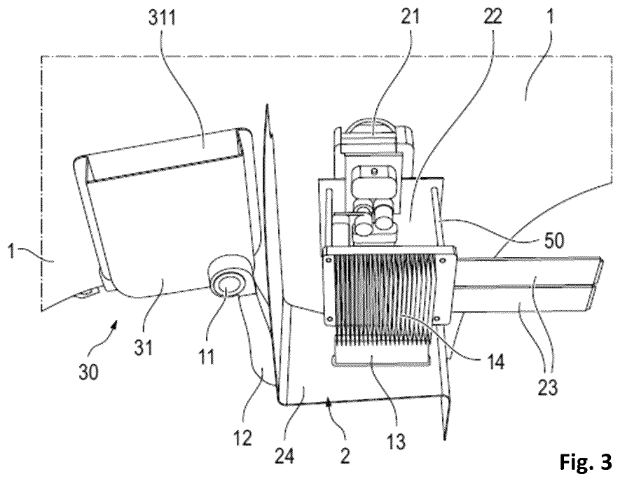

FIG. 3 shows a second embodiment of the cooling apparatus according to aspects of the invention in a perspective illustration. The second embodiment corresponds in large part to the first embodiment already explained with reference to FIG. 1, for which reason a detailed description of the already known components can be omitted at this point, and only the differences are addressed.

By contrast to the embodiment shown in FIG. 1, in the embodiment shown in FIG. 3, the charging box 21 with the charging contacts 22 and the charging lines 23 on the one hand and the forced vent 30 on the other hand are positioned one behind the other in the direction of travel of the vehicle, and not next to one another. The result is that the forced vent 30 also does not ventilate into the intermediate space 2 in which the charging box 21 is arranged. Consequently, the cooling duct 12 also does not extend in the vehicle transverse direction, but rather also in the vehicle longitudinal direction.

In the embodiment shown according to FIG. 3, the heat sink 14 is arranged spaced apart from the charging box 21 by means of a spacing apparatus 50. There is thus no direct contact to the charging contacts 22. However, the charging lines 23, which in the embodiment shown are configured as flat bus bars, are passed through the heat sink 23 and thus cooled. Due to the close proximity of the heat sink 14, there is thus also a cooling effect on the charging contacts 22 through the charging lines 23.

Due to the spacing apparatus 50, the charging lines 23 as well as the charging contacts 22 can slightly deform or move without the fastening of the heat sink 14 being affected. Thus, a thermal expansion or movement due to mechanical effects during insertion and/or removal of the plug of the charging point can be compensated.

### LIST OF REFERENCE SIGNS

1 Outer skin
11 Fan
12 Air duct
13 Air duct outlet
14 Heat sink
2 Intermediate space
21 Charging box
22 Charging contacts
23 Charging line
24 Intermediate skin
30 Forced vent
31 Acoustic hood
311 Opening of the acoustic hood
32 Forced vent
4 HV system
50 Spacing apparatus
T_{L} Temperature of the charging contacts
T_{L, permissible} Permissible temperature of the charging contacts
T_{fan, on} Switch-on temperature of the fan
T_{climatecontrol, on} Switch-on temperature of the air conditioning

What is claimed is:

1. A cooling apparatus for cooling charging contacts and/or charging lines of a charging interface in a vehicle, said cooling apparatus comprising:
a forced vent configured to convey air from an interior of the vehicle to an exterior of the vehicle,
an air duct having an air duct outlet configured to guide a flow of air from the forced vent to the charging contacts and/or the charging lines, and
a fan configured to cause the air flow in the air duct.

2. The cooling apparatus according to claim 1, wherein the forced vent comprises an acoustic hood configured to prevent sound transmission from outside the interior into the interior.

3. The cooling apparatus according to claim 2, wherein the fan is arranged in the acoustic hood.

4. The cooling apparatus according to claim 1, wherein the air duct outlet comprises air-conducting elements configured to selectively discharge air from the air duct.

5. The cooling apparatus according to claim 1, wherein the cooling apparatus further comprises a heat sink having direct contact with the charging contacts and/or the charging lines, and wherein the air duct outlet is at least partially aimed at the heat sink.

6. The cooling apparatus according to claim 5, wherein the heat sink is fixed via a spacing apparatus to a charging box carrying the charging contacts, and the heat sink carries the charging lines therewithin.

7. The cooling apparatus according to claim 1, wherein the air duct outlet is arranged at an elevation below the charging contacts and/or the charging lines.

8. A vehicle comprising the cooling apparatus according to claim 1.

9. A method for operating a cooling apparatus during a charging operation of a traction battery of a vehicle, said method comprising the steps of:
(A) detecting a temperature of charging contacts of a charging interface in a vehicle,
(B) comparing the temperature of the charging contacts to a permissible temperature of the charging contacts,
(C) if the temperature of the charging contacts is less than the permissible temperature of the charging contacts, a comparison of the temperature of the charging contacts to a switch-on temperature of the fan of the cooling apparatus takes place,
(D) if the temperature of the charging contacts is greater than the switch-on temperature of the fan, then the fan is connected,
(E) comparing the temperature of the charging contacts to a switch-on temperature of the air conditioning, and
(F) if the temperature of the charging contacts is greater than the switch-on temperature of the air conditioning, then the air conditioning is connected.

10. The method according to claim 9, wherein the switch-on temperature of the air conditioning is adjusted as a function of the temperature of the charging contacts by way of a charging management system.
